(19) United States
(12) Patent Application Publication
(10) Pub. No.: US 2008/0017890 A1
(43) Pub. Date: Jan. 24, 2008

(54) Highly dense monolithic three dimensional memory array and method for forming

(75) Inventors: Jack Yuan, Cupertino, CA (US); George Samachisa, San Jose, CA (US)

Correspondence Address: PATENT DEPT., SANDISK Corporation, 601 MCCARTHY BOULEVARD, MAILSTOP 116, MILPITAS, CA, 95035, US

(73) Assignee: SanDisk 3D LLC, Milpitas, CA (US)

(21) Appl. No.: 11/479,697

(22) Filed: Jun. 30, 2006

(51) Int. Cl. H01L 29/76; H01L 29/745

(52) U.S. Cl. 257/213

(57) ABSTRACT

A method to form a highly dense monolithic three dimensional memory array is provided. In preferred embodiments, conductive or semiconductor spacers can be formed, then used as hard masks to pattern underlying layers, forming features at sublithographic pitch. Methods of the invention minimize photomasking steps and thus simplify fabrication.

### BACKGROUND OF THE INVENTION

The invention relates to a method to form a highly dense monolithic three dimensional memory array, the array comprising multiple memory levels formed in layers deposited above a substrate.

Monolithic three dimensional memory arrays are known, as in Johnson et al., U.S. Pat. No. 6,034,882, “Vertically stacked field programmable nonvolatile memory and method of fabrication”; Knall et al., U.S. Pat. No. 6,420,215, “Three Dimensional Memory Array and Method of Fabrication”; Vyvoda et al. (MA-075); and Hemer et al., U.S. Pat. No. 6,952,030, “High-Density Three-Dimensional Memory Cell,” inter alia.

In these memory arrays, memory cell size is limited by the size of features that can be defined using conventional photolithographic techniques. Fabrication of these memory arrays can be complex.

It would thus be advantageous to increase the density of such arrays and to reduce their cost and complexity.

### SUMMARY OF THE PREFERRED EMBODIMENTS

The present invention is defined by the following claims, and nothing in this section should be taken as a limitation on those claims. In general, the invention is directed to a highly dense monolithic three dimensional memory array and methods to form such an array.

A first aspect of the invention provides for a method for forming a first memory level, the method comprising: forming a plurality of substantially parallel, substantially coplanar first rails of a first layer or layerstack, the first rails above underlying layers; conformally depositing a second layer or layerstack on the first rails; etching the second layer or layerstack to form first spacers of the second layer or layerstack; removing the first rails; and etching the underlying layers self-aligned with the first spacers, wherein the first spacers serve as hard masks during the etching step. A hard mask is a material other than photoresist that serves to pattern underlying materials during an etch step. In various embodiments, the underlying layers are semiconductor layers and conductor layers, and are etched into substantially parallel rails or pillars.

Another aspect of the invention provides for a method for forming a monolithic three dimensional memory array above a substrate, the method comprising: depositing a first conductor layer or layerstack; depositing a first semiconductor layerstack comprising a first state-change layer, the first semiconductor layerstack above the first conductor layer or layerstack; depositing a first sacrificial material above the first semiconductor layer or layerstack; patterning and etching the first sacrificial material to form first sacrificial rails; conformally depositing a second layer or layerstack on the first sacrificial rails; etching the second layer or layerstack to form first spacers; removing the first sacrificial rails; and etching the first semiconductor layerstack and the first conductor layer or layerstack to form first memory material rails wherein the first spacers serve as hard masks during the step of etching first memory material rails.

Yet another aspect of the invention provides for a monolithic three dimensional memory array above a substrate comprising: a first plurality of substantially parallel, substantially coplanar conductors extending in a first direction; a second plurality of substantially parallel, substantially coplanar conductors extending in a second direction different from the first direction, the second conductors above the first conductors; a first plurality of pillars, each first pillar disposed between one of the first conductors and one of the second conductors, each first pillar having two substantially vertical sides aligned with sidewalls of one of the first conductors, and each first pillar having two substantially vertical sides aligned with sidewalls of one of the second conductors, wherein the first conductors have a pitch of about 300 nm or less.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIG. 1 is a perspective view illustrating feature size, gap size, and pitch in repeated features.

FIGS. 2a-2e are cross-sectional views illustrating stages in formation of features formed at sizes smaller than photolithographic limits according to the present invention.

FIGS. 3a-3j are cross-sectional views illustrating stages in formation of a monolithic three dimensional memory array formed according to a preferred embodiment of the present invention. FIGS. 3e and 3f show the structure at the same stage from perpendicular views, as do FIGS. 3g and 3h, and FIGS. 3i and 3j.

FIGS. 4a-4d are cross-sectional views illustrating stages in formation of the final memory level according to a preferred embodiment of the present invention.

FIGS. 5a and 5b are cross-sectional views illustrating stages in formation of a first memory level according to an alternative embodiment of the present invention.

### DETAILED DESCRIPTION OF THE PREFERRED EMBODIMENTS

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, “Three dimensional structure memory.” The substrates may be thinned or removed from the memory levels before bonding, but as the memory levels are initially formed over separate substrates, such memories are not true monolithic three dimensional memory arrays.

A monolithic three dimensional memory array formed above a substrate comprises at least a first memory level formed at a first height above the substrate and a second memory level formed at a second height different from the first height. Three, four, eight, or indeed any number of memory levels can be formed above the substrate in such a multilevel array.

A nonvolatile memory cell can be formed by disposing a non-linear electronic device like a diode, a MOS transistor, or a bipolar transistor, and a state-change element between conductors. The data state of the memory cell (data “0” or “1”, for example) can be stored in the state of the state-change element. A state-change element is an element that can be changed between two or more readily detectable states. The difference in state may be detected as a difference in electrical resistance or current flow. A state-change element may be, for example, a fuse, an antifuse (such as a dielectric rupture antifuse), or may be formed of a material having variable or switchable resistivity, such as a chalcogenide, perovskites, or a binary metal oxide or nitride. The change in state can be permanent (as in a fuse or antifuse), forming a one-time-programmable memory cell; or reversible, forming a rewriteable memory cell.

By including a diode, or some other device exhibiting non-ohmic conduction characteristics, such memory cells can be formed in a large memory array. A diode provides electrical isolation, allowing a memory cell to be read or programmed without inadvertently programming adjacent cells sharing the same bitline or wordline.

Using methods according to the present invention, a highly dense monolithic three dimensional memory can be formed with a minimized number of photomasking steps and simplified construction.

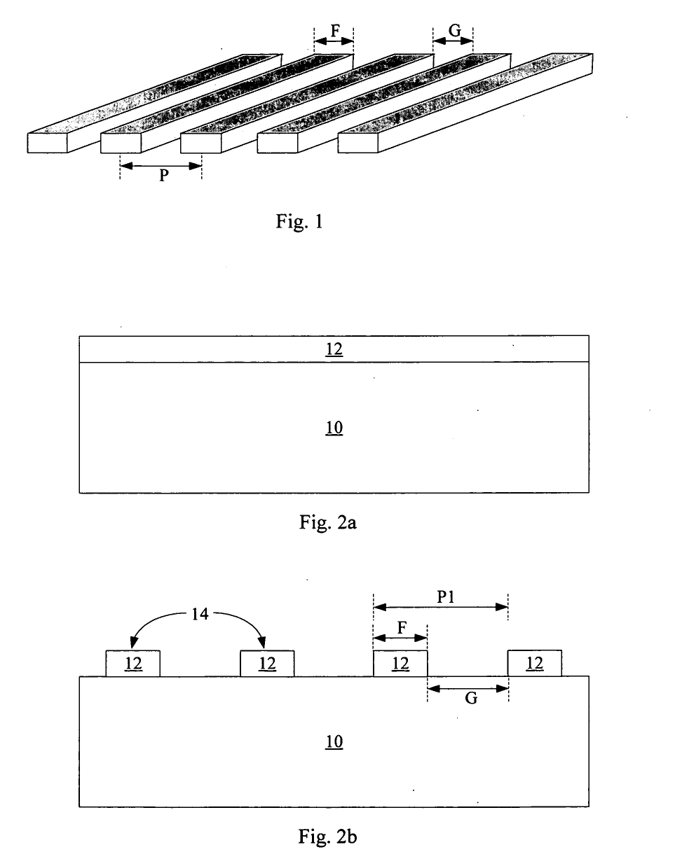

The feature size is the smallest feature or gap in an integrated circuit that is patterned by photolithographic means. In a repeated pattern, the pitch is the distance between adjacent recurrences of the same feature. For example, as shown in FIG. 1, in an array of substantially parallel rails separated by gaps, the width F of a rail, or the width G of a gap, is the feature size, while the distance P from the center of one rail to the next is the pitch. It will be seen that when patterned features and gaps between them have the same width, pitch will be twice the feature size.

Using methods of the present invention, a memory array can be formed having a pitch substantially less than twice the feature size, and features can be formed having dimensions below photolithographic limits.

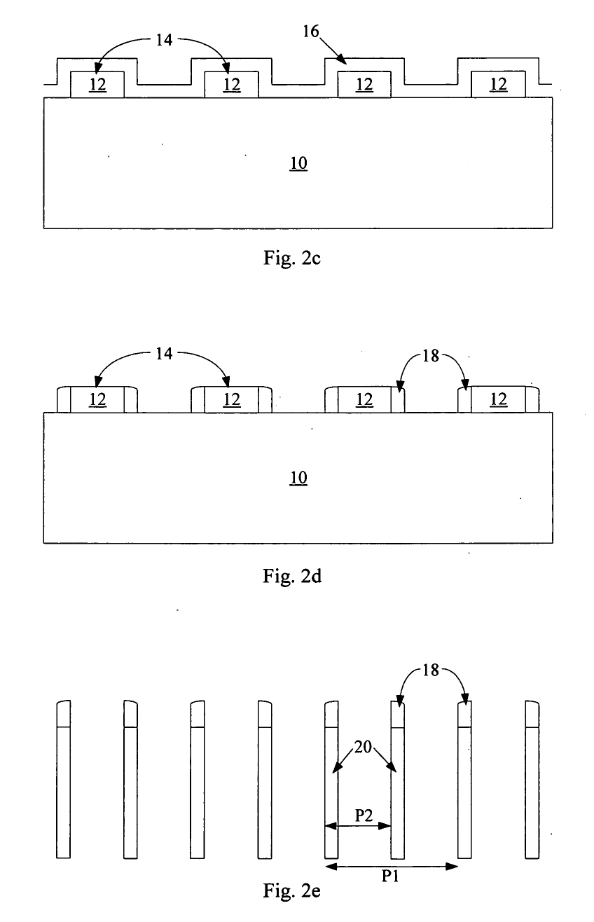

FIG. 2a shows deposited layerstack 10 including layers which will be patterned to form semiconductor devices. Layerstack 10 may comprise layers of metal, silicon or other semiconductor material, grown or deposited dielectrics, etc. Sacrificial material 12 is deposited on layerstack 10.

As shown in FIG. 2b, sacrificial material 12 is patterned and etched, using conventional photolithographic and etch techniques, to form parallel rails 14, shown here in cross-section. Rails 14 extend out of the page. Suppose the width F of each rail is 55 nm, and the width G of gaps between them is 105 nm, for a pitch P1 of 160 nm. These drawings are not to scale.

In FIG. 2c, a conductive material 16 is conformally deposited over rails 14. In this example the thickness of conductive material 16 is 25 nm. In FIG. 2d, an anisotropic etch is performed, etching conductive material 16 vertically but with little or no lateral etch component. This etch thus removes conductive material 16 from horizontal surfaces on and between rails 14, leaving spacers 18.

Finally, as in FIG. 2e, sacrificial rails 14 are removed, and spacers 18 serve as hard masks during a subsequent etch of underlying layerstack 10 into parallel rails 20. Rails 20 have a width of 25 nm and are formed at a pitch P2 of 80 nm. The pitch P1 of rails 14 of FIG. 2b is 80 nm, which is one-half the pitch P2 (160 nm) of original rails 14 in FIG. 2b, and is substantially less than double the feature size of patterned rails 14, which was 55 nm. Pitch P1 of rails 14 is shown in FIG. 2e for reference, though these rails were removed in an earlier step.

In this example, the gap width G and feature size F of rails were selected so that spacers 18 are evenly spaced at pitch P2. This arrangement is frequently advantageous, but not necessary; the relationship of gap width and feature size can be adjusted as desired. In this example, material 16 was described as conductive, and can act as an electrical interconnect to a patterned device. Depending on the structure to be formed, however, material 16, which will form the spacers 18, need not be conductive; it may be semiconductor material or a dielectric instead.

As will be described, in embodiments of the present invention, the methods illustrated in FIGS. 2a-2e can be used iteratively to pattern and etch rails and pillars in a monolithic three dimensional memory array.

### DETAILED EXAMPLE

A detailed example of fabrication of a monolithic three dimensional memory array formed according to a preferred embodiment of the present invention will be provided. For completeness, many materials, conditions, and steps will be described. It will be understood, however, that many of these details can be modified, augmented, or omitted while the results fall within the scope of the invention.

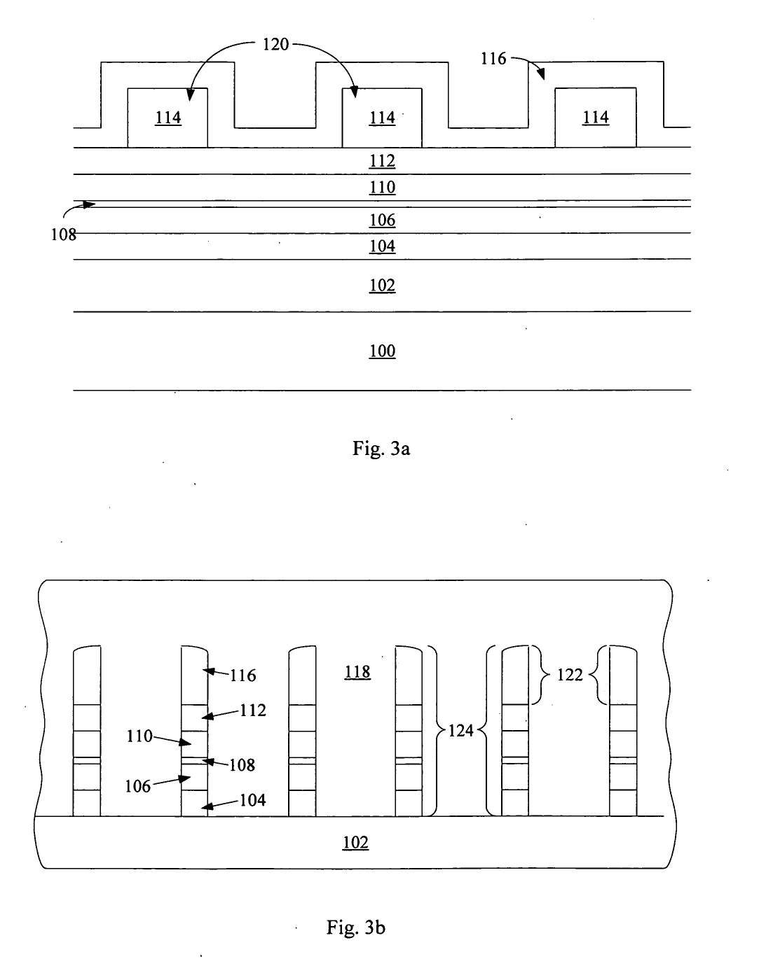

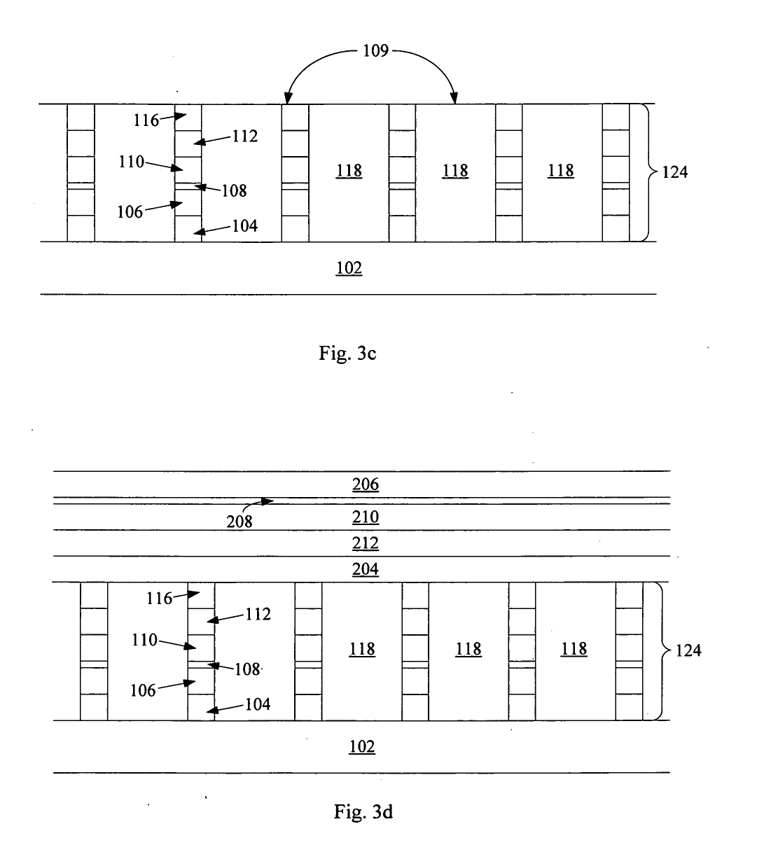

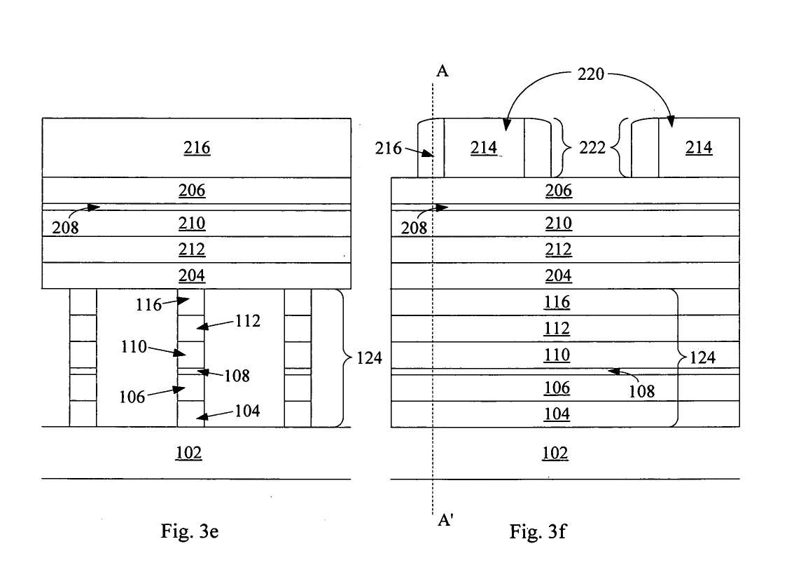

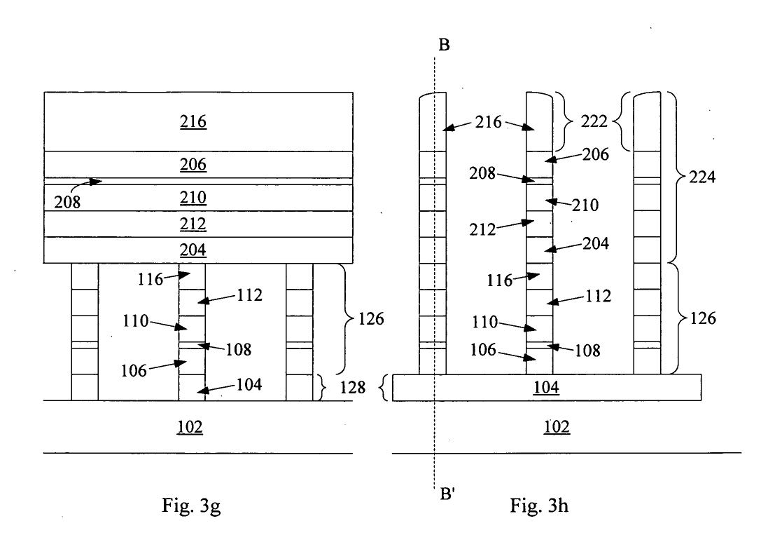

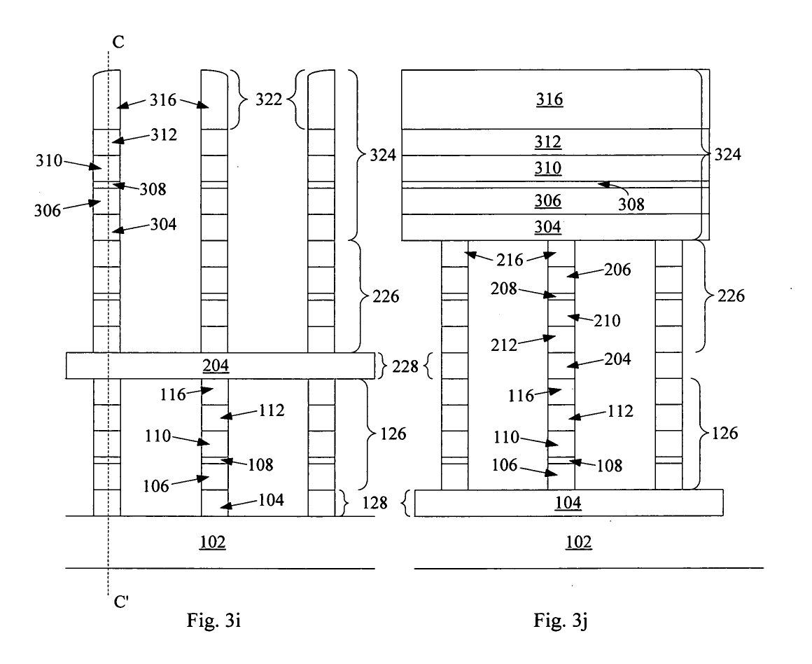

Turning to FIG. 3a, formation of the memory begins with a substrate 100. This substrate 100 can be any semiconducting substrate as known in the art, such as monocrystalline silicon, IV-IV compounds like silicon-germanium or silicon-germanium-carbon, III-V compounds, II-VII compounds, epitaxial layers over such substrates, or any other semiconducting material. The substrate may include integrated circuits fabricated therein.

An insulating layer 102 is formed over substrate 100. The insulating layer 102 can be silicon oxide, silicon nitride, high-K dielectric film, Si—C—O—H film, or any other suitable insulating material.

Conductive layer 104 is deposited on insulating layer 102. Conductive layer 104 is any appropriate conductive material or materials, including metals, metal alloys, conductive nitrides, conductive metal silicides, or heavily doped semiconductor material. For example, conductive layer 104 may be titanium nitride, and may have any appropriate thickness, for example between about 20 and about 100 μm, preferably about 50 μm. In some embodiments, conductive layer 104 may be a layerstack of two or more conductive materials.

Next a first heavily doped semiconductor layer 106 is deposited on conductive layer 104. Semiconductor layer 106 is preferably silicon, germanium, or an alloy of silicon and/or germanium. For simplicity, this example will describe the semiconductor material used in this and later semiconductor layers as silicon, but it will be understood that other semiconductor materials may be used for any or all semiconductor layers. Layer 106 is doped with either p-type or n-type dopants. For example, layer 106 may be doped with a p-type dopant such as boron or BF₂. Layer 106 may be any thickness, for example between about 10 and about 50 nm, preferably about 20 nm.

Heavily doped p-type silicon layer 106 and subsequent silicon layers can be deposited by any known method, including chemical vapor deposition, atomic layer deposition, or sputtering. Doping can be by any known method, including in situ doping, diffusion of doping impurities, or ion implantation. When silicon is deposited by sputtering, an n-type or p-type sputtering target can supply the dopant. Alternatively, dopant atoms may be implanted or otherwise provided in a layer adjacent to a silicon layer which is to be doped; for example dopant may be implanted in a conductive layer immediately beneath the silicon layer to be doped. During subsequent thermal cycles, dopant will diffuse from the adjacent doped layer into the target silicon layer.

Depending on deposition temperature, semiconductor material such as silicon will be deposited in an amorphous or crystalline state. Amorphous semiconductor material can be crystallized into polycrystalline semiconductor material by annealing. This anneal may be performed as a separate step, or may take place as a result of subsequent thermal steps, and a separate anneal may not be required. Polycrystalline silicon will be referred to herein as polysilicon.

State-change layer 108 can be an antifuse. In a preferred embodiment, state-change layer 108 is a dielectric layer or layerstack which will behave as a dielectric rupture antifuse. For example, state-change layer 108 can be a layer of silicon dioxide grown by oxidizing a portion of silicon layer 106 in a rapid thermal anneal. Alternatively, a dielectric material, for example a high-K dielectric such as Al₂O₃, can be deposited instead. In this example, state-change layer 108 will be described as a dielectric rupture antifuse, but it will be understood that an of the other state change materials named herein could be used instead. Antifuse 108 is preferably very thin, for example less than about 5 nm.

Undoped or lightly doped silicon layer 10 is deposited on antifuse 108. Undoped or lightly doped silicon layer 10 may be any thickness, for example between about 10 and about 50 nm, preferably about 20 nm. If layer 10 is lightly doped, it is preferably doped with an n-type dopant such as phosphorus or arsenic.

Heavily doped n-type silicon layer 112 is deposited on undoped or lightly doped silicon layer 110. Heavily doped n-type silicon layer 112 may be any thickness, for example between about 10 and about 50 nm, preferably about 20 nm.

If state-change layer 108 is a dielectric rupture antifuse layer, it will be insulating in its initial state. When subjected to sufficient voltage, it will suffer dielectric breakdown, and a permanent conductive path will be formed through it. Upon rupture of antifuse 108, heavily doped n-type layer 112, undoped or lightly doped layer 10, and heavily doped p-type layer 106 will form a vertically oriented junction diode. This diode is a p-i-n diode.

In alternative embodiments, state-change layer 108 is a fusible element or a resistance-switching element such as a chalcogenide layer. In this case, state-change layer 108 should not be located such that it prevents formation of a p-n junction. For example, if undoped or lightly doped layer 110 is in fact lightly n-doped, the diode is formed by the p-n junction between heavily doped p-type layer 106 and layer 110, and state-change layer 108 should be located above or below this junction. For example, state-change layer 108 can be located below heavily doped p-type layer 106, above undoped or lightly doped layer 110, or above heavily doped n-type layer 112. This placement applies to every state-change layer formed in subsequent memory levels.

In another alternative one-time-programmable embodiment, the diode itself can behave as a fuse. If the dimension of the pillar is sufficiently small and the power during programming is sufficiently high, the diode can be destroyed during programming, leaving a memory cell with very high resistance. In this case the diode serves as the state change element.

A junction diode is a semiconductor device with the property of conducting current more easily in one direction than the other, having two terminal electrodes, and made of semiconducting material which is p-type at one electrode and n-type at the other. Examples are p-n diodes, p-i-n diodes, and Zener diodes. In alternative embodiments, the diode can be a Schottky barrier diode.

Next a layer of sacrificial material 114 is deposited on heavily doped n-type region 112. This layer will not be present in the final device, and thus can be any material that is compatible with process integration requirements. For example, the material should readily adhere to and should have good etch selectivity with both silicon and the spacer material to be deposited in an upcoming step. In the present embodiment, sacrificial material 114 is silicon dioxide, though other materials can be used. Preferably sacrificial layer 114 is between about 50 and about 200 nm thick, most preferably about 100 nm thick.

Layer 114 is patterned and etched by conventional means to form substantially parallel sacrificial rails 120. Sacrificial rails 120 are shown in cross-section, extending out of the page. In this example, sacrificial rails 120 are about 55 nm wide, and gaps between them are about 105 nm wide, so that the pitch of sacrificial rails 120 is about 160 nm. These feature and gap widths have been selected such that eventual spacers to be formed will be evenly spaced, but other dimensions may be selected; for example the pitch of sacrificial rails may be about 320 nm or less, for example 200 nm or less, for example about 160 nm or less. Feature and gap sizes may be adjusted accordingly. These drawings are not to scale.

A layer 116 of a conductive material is conformally deposited over sacrificial rails 120. Conductive layer 116 can be either a single material or a conductive layerstack, comprising any appropriate conductive material such as a metal, metal alloy, conductive nitride, or conductive metal silicide. In the present embodiment, layer 116 is preferably titanium nitride, though tantalum nitride, tungsten nitride, and many other appropriate conductive materials can be used instead. The thickness of conductive layer 116 can be as desired, for example about 25 nm. The structure at this point is shown in FIG. 3a.

Turning to FIG. 3b, an anisotropic etch is performed, removing layer 116 from the top of sacrificial rails 120 and between them, forming spacers 122. Sacrificial rails 120 are then removed by a dry or wet etch. (To save space, substrate 100 is omitted in these and subsequent figures. Its presence should be assumed.)

Next spacers 122 serve as hard masks while heavily doped n-type silicon layer 112, undoped or lightly doped silicon layer 110, antifuse layer 108, heavily doped p-type silicon layer 106, and conductive layer 104 are etched into substantially parallel first memory material rails 124. First memory rails 124 comprise semiconductor rails (of layers 106, 110, and 112) formed above conductor rails (of layer 104). Dielectric material 118, which is deposited to fill gaps between first memory material rails 124, can be any appropriate dielectric, for example a high-density plasma (HDP) oxide.

Summarizing, memory rails 124 were formed by forming a plurality of substantially parallel, substantially coplanar first sacrificial rails 120 of a first layer or layerstack, the first rails above underlying layers; conformally depositing a second layer or layerstack 116 on the first rails; etching the second layer or layerstack to form first spacers 122 of the second layer or layerstack; removing the first rails 120; and etching the underlying layers self-aligned with the first spacers 122, wherein the first spacers serve as hard masks during the etching step. The underlying layers here comprise semiconductor layers and conductor layers.

As shown in FIG. 3c, a planarization step, for example by chemical mechanical polishing (CMP) or etchback, removes overfill of dielectric 118 exposing tops of first memory rails 124 and dielectric 118 at a substantially planar surface 109. This planarization step removes some thickness of conductive material 116, leaving, for example, 10-20 nm of thickness.

Turning to FIG. 3d, layers are deposited on planar surface 109. Conductive layer 204 can be of a material and thickness comparable to conductive layer 104 of first memory rails 124. A silicon diode layerstack including a state-change layer is deposited. This stack may be the same as the layers in first memory rails 124; in this example, the polarity of the diode is reversed. Heavily doped n-type silicon layer 212 is deposited first, on conductive layer 204, followed by undoped or lightly doped silicon layer 210, antifuse layer 208, and heavily doped p-type silicon layer 206. These layers are preferably formed in the same manner and having the same thicknesses as the corresponding layers in first memory rails 124. As in the earlier stack, if antifuse layer 208 is replaced with a resistance-switching element or a fuse element, it should be located such that it does not prevent formation of a p-n junction.

The view of FIG. 3e is the same as that of FIG. 3d, while the view of FIG. 3f is a 90° rotation view. FIG. 3e is viewed along line A-A′ of FIG. 3f. Referring to both FIGS. 3e and 3f, sacrificial material 214 is deposited on heavily doped p-type silicon layer 206, and is patterned and etched into substantially parallel rails 220. Rails 220 preferably have the same width and pitch as rails 120 of FIG. 3a, but their width and pitch may be different if this is preferred. Note that rails 220 of sacrificial material 214 extend in a different direction than first memory material rails 124, preferably substantially perpendicular to them. Conductive material 216, which may be any appropriate conductive material, such as titanium nitride, is conformally deposited over rails 220. An anisotropic etch removes conductive material 216 from the top of and between rails 220, leaving spacers 222. FIGS. 3e and 3f illustrate the structure at this point.

FIG. 3g shows the structure from the same view as FIG. 3e, while FIG. 3h shows the same view as FIG. 3f, the view of FIG. 3g along line B-B′ of FIG. 3h. Referring to FIGS. 3g and 3h, after removal of sacrificial rails 220 by a wet or dry etch, spacers 222 serve as hard masks while heavily doped p-type silicon layer 206, undoped or lightly doped silicon layer 210, antifuse layer 208, heavily doped p-type silicon layer 212, and conductive layer 204 are etched into substantially parallel second memory material rails 224.

Etching does not stop at this point, however. The etch continues, etching conductive material 116, heavily doped n-type layer 112, undoped or lightly doped layer 110, antifuse layer 108, and heavily doped p-type layer 106 of first memory rails 124. Etching stops on conductive layer 104. This etch is perpendicular to the etch that formed first memory rails 124; thus these doubly-etched layers, 116, 112, 110, 108, and 106 form first pillars 126. Conductive layer 104, however, is not etched; thus this material remains in first conductor rails 128. First conductor rails 128 will serve as bitlines in the completed memory array. FIGS. 3g and 3h shows the structure after this etch is complete. Recall that in the structure formed in FIGS. 2a-2d, final rails 20 are spaced at one-half the pitch of sacrificial rails 14. Similarly, first conductor rails 128 are at one-half the pitch of sacrificial rails 120 of FIG. 3b; thus they are preferably formed at a pitch of 80 nm or less, though in other embodiments the pitch of first conductor rails 128 (and subsequent conductor rails) may be about 160 nm or less, for example 100 nm or less. In less preferred embodiments, the pitch of first conductor rails 128 may be larger, for example 300 nm or less, 200 nm or less, or 180 nm or less.

The process is repeated. After deposition of dielectric material to fills gaps between second memory material rails 224 and a CMP step to remove dielectric overfill expose tops of second memory rails 224 at a planar surface, turning to FIGS. 3i and 3j, the next conductor and diode stack is deposited on this planar surface. (FIG. 3i shows the structure viewed from the same angle as 3g, while FIG. 3j is viewed from the same angle as FIG. 3h. FIG. 3j is viewed along line C-C′ of FIG. 3i.) In a preferred embodiment these layers include titanium nitride layer 304, heavily doped p-type silicon layer 306, antifuse layer 308 (this antifuse is again preferably thermally grown), undoped or lightly doped silicon layer 310, and heavily doped n-type silicon layer 312. Spacers 322 are of conductive layer 316 formed as before by conformally depositing layer 316 over sacrificial material which has been patterned and etched into substantially parallel rails (not shown), which are removed after the spacer etch. Spacers 322 preferably have the same width and pitch as spacers 122 in FIG. 3a.

As before, spacers 322 serve as hard masks while heavily doped n-type silicon layer 312, undoped or lightly doped silicon layer 310, antifuse layer 308, heavily doped p-type silicon layer 306, and conductive layer 304 are etched into substantially parallel third memory material rails 324. Third memory rails 324 are preferably substantially perpendicular to second memory rails 224 in FIGS. 3g and 3h, and preferably substantially parallel to first conductor rails 128.

Also as before, the etch continues, etching conductive material 216, heavily doped p-type layer 206, antifuse layer 208, undoped or lightly doped layer 210, and heavily doped n-type layer 212, the layers forming second memory rails 224 of FIGS. 3g and 3h. Etching stops before conductive layer 204 is etched. This etch is perpendicular to the etch that formed second memory rails 224; thus these doubly-etched layers, 216, 206, 208, 210 and 212, form second pillars 226. Conductive layer 204, however, is not etched; thus this material remains in second conductor rails 228.

First conductor rails 128, first pillars 126, and second conductor rails 228 form a first memory level. First conductor rails 128 serve as bitlines, while second conductor rails 228 serve as wordlines. Each of first pillars 126 has a substantially square cross section, having four sides. Two opposing sides were formed in the same etch that formed first conductor rails 128, and thus these side are aligned with the sidewalls of first conductor rails 128. The other two opposing sides were formed in the same etch step that formed second conductor rails 228, and thus these sides are aligned with the sidewalls of second conductor rails 228.

The process described can be repeated to form additional memory levels. For example, once layers 306, 308, 310, and 312 are etched into pillars in a subsequent iteration, conductor layer 304 will remain as third conductor rails. A second memory level will include second conductor rails 228, second pillars 226, and these third conductor rails.

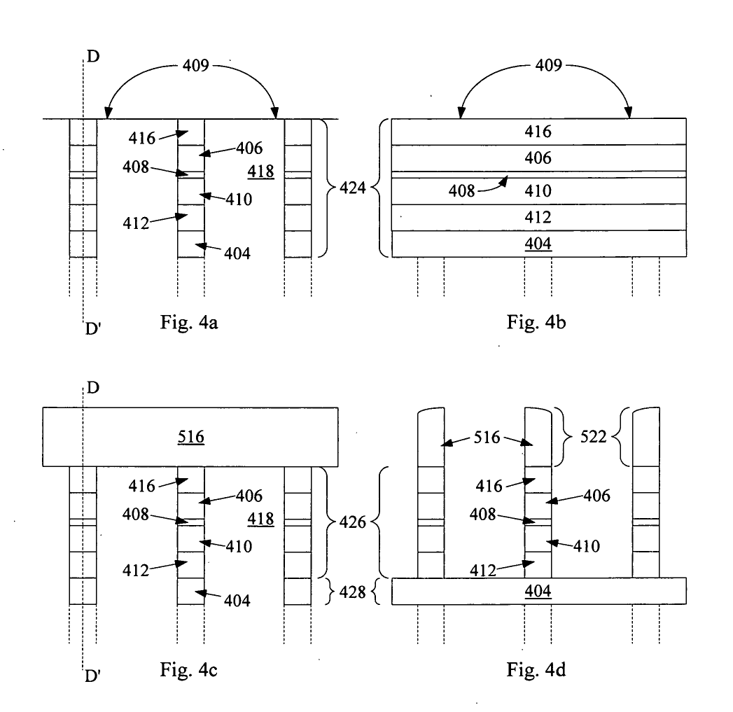

Turning to FIG. 4a, a final memory level will be formed above final memory rails 424, which have been exposed at planar surface 409 after gap fill with dielectric material 418. This final memory level can be the third, fourth, fifth, or higher memory level formed above the substrate. Dashed lines indicate pillars of a lower memory level. FIG. 4b shows the same structure viewed perpendicularly along line D-D′.

A sacrificial material (not shown) is deposited directly on planar surface 409, then the sacrificial material patterned and etched into sacrificial rails (not shown) which extend perpendicular to final memory rails 424. Turning to FIGS. 4c and 4d, conductive material 516 is conformally deposited over the sacrificial rails, a spacer etch performed to form spacers 522, and the sacrificial rails removed. Spacers 522, which also extend perpendicular to final memory rails 424, serve as hard masks to etch the layers of final memory rails 424, including conductive layer 416, heavily doped p-type silicon layer 406, antifuse layer 408, undoped or lightly doped silicon layer 410, and heavily doped n-type silicon layer 412, forming final pillars 426. The etch stops before etching conductive layer 404, leaving conductor rails 428. Dielectric fill will be deposited between spacers 522, which will serve as top conductor rails for the final memory level just formed.

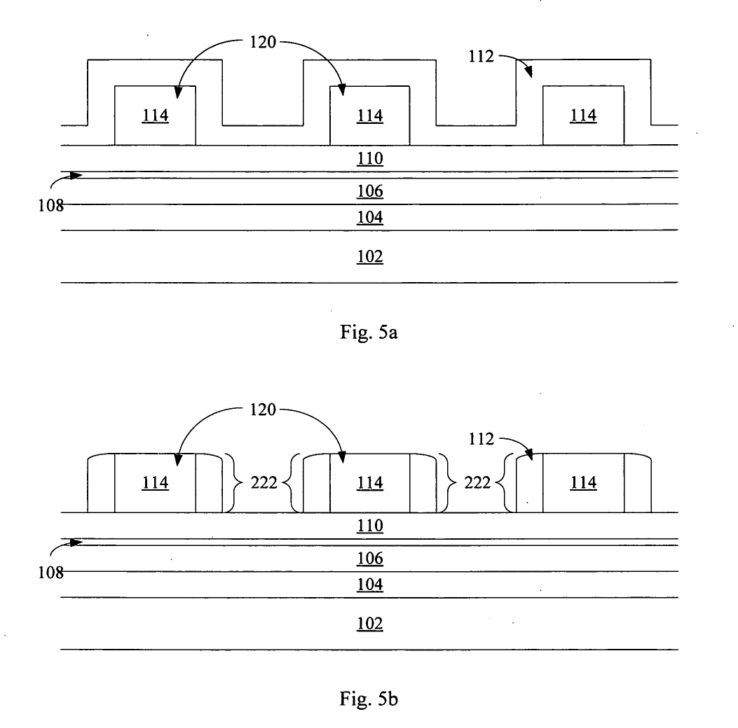

For clarity one detailed example of the present invention has been provided, but many variations can be envisioned and fall within the scope of the invention. In the memory array described, a conductive layer appeared at both the bottom and the top of each deposited stack, for example layers 104 and 116; eventually these layers became the bottom conductors 128 and the spacers 122 serving as hard masks. The use of a conductive material as the hard mask at the top of each rail is preferred: this layer provides good electrical contact between the diode of each pillar and the overlying conductor, and the fact that the hard masks are a material other than silicon allows them improved longevity during the etch that defines the pillars. If desired, however, the top conductive layer could be omitted, and the heavily doped layer of each diode could instead be used to form spacers which will serve as hard masks. For example, turning to FIG. 5a, in one embodiment, conductive layer 104, heavily doped p-type silicon layer 106, antifuse layer 108, and undoped or lightly doped layer 110 are deposited above insulating layer 102. Sacrificial rails 120 are formed on undoped or lightly doped layer 110. Heavily doped n-type layer 112 is conformally deposited over rails 120. As shown in FIG. 5b, an anisotropic etch forms spacers 122, which are formed of heavily doped n-type material rather than of conductive material 116 as in FIG. 3b. Fabrication continues as in prior embodiments; spacers 122 serve as hard masks to etch a first memory rail.

In the detailed example provided earlier, polarity of diodes alternated from one level to the next. Referring to FIG. 3j, for example, in the first memory level, the diodes had a heavily doped p-type layer (106) at the bottom and a heavily doped n-type (112) layer at the top, while on the second memory level, the diodes had a heavily doped n-type layer (212) at the bottom and a heavily doped p-type layer (206) at the top. In other embodiments, other arrangements may be preferred; for example, it may be preferred for all diodes on all memory levels to have p-type layers at the bottom and n-type layers at the top, or vice versa.

When the state-change element is an antifuse, in preferred embodiments it is located at the diode junction, and is thus either between the bottom heavily doped layer and the undoped or lightly doped layer, or between the top heavily doped layer and the undoped or lightly doped layer. In other alternative embodiments, the state-change element may be elsewhere in the memory cell; above or below the polysilicon stack, for example. The state-change element can be a part of the pillars, as shown, or, alternatively, may be coextensive with the conductor rails.

Additional layers that have not been mentioned, such as barrier, adhesion, or etch stop layers, may be included in one or more memory levels of the memory array.

Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A method for forming a first memory level, the method comprising:
forming a plurality of substantially parallel, substantially coplanar first rails of a first layer or layerstack, the first rails above underlying layers;
conformally depositing a second layer or layerstack on the first rails;
etching the second layer or layerstack to form first spacers of the second layer or layerstack;
removing the first rails; and
etching the underlying layers self-aligned with the first spacers, wherein the first spacers serve as hard masks during the etching step.

2. The method of claim 1 wherein the step of etching the underlying layers comprises:
etching first semiconductor layers; and
etching first conductor layers.

3. The method of claim 2 wherein, during the step of etching the first semiconductor layers, the first semiconductor layers are etched into a first plurality of substantially parallel semiconductor rails.

4. The method of claim 3 wherein the first rails are spaced at a first pitch and the first semiconductor rails are spaced at a second pitch, the second pitch less than the first pitch.

5. The method of claim 4 wherein the second pitch is about one-half the first pitch.

6. The method of claim 2 wherein, during the step of etching the first conductor layers, the first semiconductor layers are etched into substantially parallel conductor rails.

7. The method of claim 6 wherein the first rails are spaced at a first pitch and the first conductor rails are spaced at a second pitch, the second pitch less than the first pitch.

8. The method of claim 7 wherein the second pitch is about one-half the first pitch.

9. The method of claim 2 wherein, during the step of etching the first semiconductor layers, the first semiconductor layers are etched into a plurality of first semiconductor pillars.

10. The method of claim 9 wherein the first rails are spaced at a first pitch and the first semiconductor pillars are spaced at a second pitch, the second pitch less than the first pitch.

11. The method of claim 10 wherein the second pitch is about one-half the first pitch.

12. The method of claim 9 wherein the first semiconductor layers comprise:
a first heavily doped semiconductor layer of a first conductivity type; and
a second heavily doped semiconductor layer of a second conductivity type, the second conductivity type opposite the first, the second heavily doped semiconductor layer above the first heavily doped semiconductor layer.

13. The method of claim 12 wherein the first semiconductor layers further comprise a third undoped or lightly doped semiconductor layer of the first or the second conductivity type, the undoped or lightly doped semiconductor layer disposed between the first heavily doped layer and the second heavily doped layer.

14. The method of claim 13 wherein each first pillar comprises a state-change element.

15. The method of claim 14 wherein the state-change element of each first pillar is a dielectric rupture antifuse.

16. The method of claim 14 wherein the dielectric rupture antifuse of each first pillar is disposed either:
a) between the undoped or lightly doped semiconductor layer and the first heavily doped semiconductor layer, or
b) between the undoped or lightly doped semiconductor layer and the second heavily doped semiconductor layer, or
c) above and in contact with the second heavily doped semiconductor layer, or
d) below and in contact with the first heavily doped semiconductor layer.

17. The method of claim 16 wherein, after rupture of the dielectric rupture antifuse, the first and second heavily doped semiconductor layers and the undoped or lightly doped semiconductor layer of each pillar form a vertically oriented p-i-n diode.

18. The method of claim 15 wherein the dielectric rupture antifuse comprises a silicon oxide layer.

19. The method of claim 14 wherein the state-change element of each first pillar comprises a chalcogenide material.

20. The method of claim 19 wherein the state-change element of each first pillar is disposed either:
a) above and in contact with the second heavily doped semiconductor layer, or
b) below and in contact with the first heavily doped semiconductor layer.

21. The method of claim 14 wherein the state-change element of each first pillar comprises a fuse element.

22. The method of claim 2 wherein the first semiconductor layers comprise polycrystalline semiconductor material.

23. The method of claim 22 wherein the polycrystalline semiconductor material comprises silicon.

24. The method of claim 22 wherein the polycrystalline semiconductor material comprises an alloy of silicon and/or germanium.

25. The method of claim 2 wherein the first semiconductor layers comprise:
a first heavily doped semiconductor layer of a first conductivity type; and
a second heavily doped semiconductor layer of a second conductivity type, the second conductivity type opposite the first, the second heavily doped semiconductor layer above the first heavily doped layer.

26. The method of claim 25 wherein the first semiconductor layers further comprise a third undoped or lightly doped layer of the first or the second conductivity type, the undoped or lightly doped layer disposed between the first heavily doped layer and the second heavily doped layer.

27. The method of claim 1 wherein the first memory level is formed above a substrate.

28. The method of claim 27 wherein the substrate is monocrystalline semiconductor material.

29. The method of claim 1 wherein the second layer or layerstack comprises a metal, metal alloy, conductive nitride, or conductive metal silicide.

30. A method for forming a monolithic three dimensional memory array above a substrate, the method comprising:
depositing a first conductor layer or layerstack;
depositing a first semiconductor layerstack comprising a first state-change layer, the first semiconductor layerstack above the first conductor layer or layerstack;
depositing a first sacrificial material above the first semiconductor layer or layerstack;
patterning and etching the first sacrificial material to form first sacrificial rails;
conformally depositing a second layer or layerstack on the first sacrificial rails;
etching the second layer or layerstack to form first spacers;
removing the first sacrificial rails; and
etching the first semiconductor layerstack and the first conductor layer or layerstack to form first memory material rails wherein the first spacers serve as hard masks during the step of etching first memory material rails.

31. The method of claim 30 further comprising:
depositing a second semiconductor layerstack comprising a second state-change layer above the first memory material rails;
depositing a second sacrificial material above the second semiconductor layerstack;
patterning and etching the second sacrificial material to form second sacrificial rails;
conformally depositing a third layer or layerstack on the second sacrificial rails;
etching the third layer or layerstack to form second spacers;
removing the second sacrificial rails; and
etching the second semiconductor layerstack to form second memory material rails, wherein the second spacers serve as hard masks during the step of etching the second memory material rails.

32. The method of claim 31 further comprising:
before the step of depositing the second semiconductor layerstack,
depositing a dielectric fill material between the first memory material rails; and
planarizing the dielectric fill material and the first memory material rails to form a first substantially planar surface,
wherein the second semiconductor layerstack is deposited above the first substantially planar surface.

33. The method of claim 32 wherein the planarizing step is performed by chemical mechanical planarization.

34. The method of claim 32 wherein the planarizing step is performed by etchback.

35. The method of claim 31 wherein the first memory material rails extend in a first direction and the second memory material rails extend in a second direction, the first direction different from the second direction.

36. The method of claim 35 wherein the first direction is substantially perpendicular to the second direction.

37. The method of claim 35 further comprising etching the first semiconductor layerstack to form first semiconductor pillars.

38. The method of claim 37 wherein the first state-change layer comprises a dielectric rupture antifuse.

39. The method of claim 38 wherein the dielectric rupture antifuse comprises silicon oxide.

40. The method of claim 37 wherein, after rupture of the dielectric rupture antifuse, the first semiconductor layerstack of each first pillar comprises a semiconductor junction diode.

41. The method of claim 37 wherein the first state-change layer comprises a chalcogenide layer.

42. The method of claim 37 further comprising:
depositing a third semiconductor layerstack above the second memory material rails;
depositing a third sacrificial material above the third semiconductor layerstack;
patterning and etching the third sacrificial material to form third sacrificial rails;
conformally depositing a fourth layer or layerstack on the third sacrificial rails;
etching the fourth layer or layerstack to form third spacers;
removing the third sacrificial rails; and
etching the third semiconductor layerstack to form third memory material rails wherein the third spacers serve as hard masks during the step of etching the third memory material rails.

43. The method of claim 42 wherein the third memory material rails extend in the first direction.

44. The method of claim 43 further comprising etching the second semiconductor layerstack to form second semiconductor pillars.

45. The method of claim 44 wherein the monolithic three dimensional memory array comprises:
a first memory level, the first memory level comprising the first semiconductor pillars; and
a second memory level, the second memory level comprising the second semiconductor pillars.

46. The method of claim 30 wherein the substrate is monocrystalline silicon.

47. The method of claim 30 wherein the first conductor layer or layerstack comprises a metal, metal alloy, conductive nitride, or conductive metal silicide.

48. The method of claim 47 wherein the first conductor layer or layerstack comprises titanium nitride.

49. The method of claim 30 wherein the first semiconductor layerstack comprises polycrystalline semiconductor material.

50. The method of claim 49 wherein the polycrystalline semiconductor material comprises silicon, germanium or an alloy of silicon and/or germanium.

51. The method of claim 30 wherein the step of depositing the first semiconductor layerstack comprises depositing silicon, germanium, or an alloy of silicon and/or germanium by chemical vapor deposition.

52. The method of claim 30 wherein the step of depositing the first semiconductor layerstack comprises depositing silicon, germanium, or an alloy of silicon and/or germanium by atomic layer deposition.

53. The method of claim 30 wherein the step of depositing the first semiconductor layerstack comprises depositing silicon, germanium, or an alloy of silicon and/or germanium by sputtering.

54. The method of claim 53 wherein the first semiconductor layerstack includes n-type or p-type dopants introduced by sputtering.

55. A monolithic three dimensional memory array above a substrate comprising:
a first plurality of substantially parallel, substantially coplanar conductors extending in a first direction;
a second plurality of substantially parallel, substantially coplanar conductors extending in a second direction different from the first direction, the second conductors above the first conductors;
a first plurality of pillars, each first pillar disposed between one of the first conductors and one of the second conductors, each first pillar having two substantially vertical sides aligned with sidewalls of one of the first conductors, and each first pillar having two substantially vertical sides aligned with sidewalls of one of the second conductors,
wherein the first conductors have a pitch of about 300 nm or less.

56. The monolithic three dimensional memory array of claim 55 wherein each first pillar comprises:
a first heavily doped semiconductor layer of a first conductivity type;
a second heavily doped semiconductor layer of a second conductivity type opposite the first conductivity type; and
a state-change element.

57. The monolithic three dimensional memory array of claim 56 wherein the state-change element of each first pillar is a dielectric rupture antifuse.

58. The monolithic three dimensional memory array of claim 57 wherein the dielectric rupture antifuse of each first pillar comprises a silicon oxide layer.

59. The monolithic three dimensional memory array of claim 56 wherein the state-change element of each first pillar comprises a chalcogenide layer.

60. The monolithic three dimensional memory array of claim 56 wherein the state-change element of each first pillar comprises a fuse.

61. The monolithic three dimensional memory array of claim 55 wherein the first conductors, first pillars, and second conductors comprise a first memory level, the first memory level comprising first memory cells.

62. The monolithic three dimensional memory array of claim 55 wherein the first conductors comprise a metal, metal alloy, conductive nitride, or conductive metal silicide.

63. The monolithic three dimensional memory array of claim 55 wherein the first pillars comprise polycrystalline semiconductor material.

64. The monolithic three dimensional memory array of claim 55 further comprising:
a third plurality of substantially parallel, substantially coplanar conductors extending in the first direction;
a second plurality of pillars, each second pillar disposed between one of the second conductors and one of the third conductors, each second pillar having two substantially vertical sides aligned with sidewalls of one of the second conductors, and each second pillar having two substantially vertical sides aligned with sidewalls of one of the third conductors.

65. The monolithic three dimensional memory array of claim 55 wherein the first conductors have a pitch of about 200 nm or less.

66. The monolithic three dimensional memory array of claim 55 wherein the first conductors have a pitch of about 180 nm or less.
